(19) United States
(12) Patent Application Publication
(10) Pub. No.: US 2011/0109762 A1
(43) Pub. Date: May 12, 2011

(54) PIXEL AND IMAGE PROCESSING DEVICES HAVING THE SAME

(76) Inventors: Yoon Dong PARK, Yongin-si (KR); Suk Pil KIM, Yongin-si (KR)

(21) Appl. No.: 12/940,534

(22) Filed: Nov. 5, 2010

(30) Foreign Application Priority Data
Nov. 6, 2009 (KR) 10-2009-0106891

(51) Int. Cl. H04N 5/228; H01L 27/14; H01L 25/00; H04N 5/335

(52) U.S. Cl. 348/222.1; 250/208.1; 250/332; 348/308; 257/E31.085; 348/E05.031

(57) ABSTRACT

A pixel of an image sensor, the pixel including a plurality of photoelectric conversion elements arranged in a semiconductor substrate; and a first transfer circuit for sequentially transferring photo-charges generated by each of the plurality of photoelectric conversion elements to a first floating diffusion node.

### BACKGROUND

1. Field

Embodiments relate to an image sensor, and more particularly, to a pixel capable of sequentially transferring photo-charges generated by each of a plurality of photoelectric conversion elements to a floating diffusion node by using a single transfer circuit, an image sensor including the pixel, and an image processing device including the image sensor.

2. Description of the Related Art

Each unit pixel of a complementary metal oxide semiconductor (CMOS) image sensor that is manufactured according to a CMOS process includes a single photoelectric conversion element and a plurality of transistors, for example, 3, 4, or 5 transistors. The CMOS image sensor includes a photoelectric conversion element for converting an optical signal into an electrical signal, and a circuit part for processing the electrical signal output from the photoelectric conversion element. Such CMOS image sensors transfer photo-charges generated by each of the photoelectric conversion elements to a floating diffusion node using a respective one of a plurality of single transfer transistors.

### SUMMARY

Embodiments are therefore directed to a pixel, which substantially overcomes one or more of the problems due to the limitations and disadvantages of the related art.

It is therefore a feature of an embodiment to provide a pixel capable of sequentially transferring photo-charges generated by each of a plurality of photoelectric conversion elements formed within the pixel to a floating diffusion node using only a single transfer circuit.

It is therefore a separate feature of an embodiment to provide an image sensor including a pixel capable of sequentially transferring photo-charges generated by each of a plurality of photoelectric conversion elements formed within the pixel to a floating diffusion node using only a single transfer circuit, e.g., a single transistor.

It is therefore a separate feature of an embodiment to provide an image processing device including an image sensor including a pixel capable of sequentially transferring photo-charges generated by each of a plurality of photoelectric conversion elements formed within the pixel to a floating diffusion node using only a single transfer circuit, e.g., a single transistor.

It is therefore a separate feature of an embodiment to provide a pixel adapted to transfer photo-charges generated by a plurality of photoelectric conversion elements formed within the pixel to a floating diffusion node by a single transfer circuit, e.g., a single transistor.

It is therefore a separate feature of an embodiment to provide an image processing device including a pixel in which photo-charges generated by each of a plurality of photoelectric conversion elements formed within the pixel may be transferred to a floating diffusion node by a single transfer circuit, e.g., a single transistor.

It is therefore a separate feature of an embodiment to provide an image sensor adapted to simplify integration thereof by sharing a single transfer circuit among a plurality, e.g., all, of the photoelectric conversion elements.

At least one of the above and other features and advantages may be realized by providing a pixel of an image sensor, the pixel including a plurality of photoelectric conversion elements arranged in a semiconductor substrate, and a first transfer circuit adapted to transfer photo-charges generated by at least two of the plurality of photoelectric conversion elements to a first floating diffusion node.

The first transfer circuit may be adapted to transfer photo-charges generated by all of the photoelectric conversion elements of the pixel to the first floating diffusion node.

The first transfer circuit may be adapted to transfer the photo-charges generated by each of the plurality of photoelectric conversion elements to the first floating diffusion node in response to a corresponding voltage level from among a plurality of voltage levels.

The first transfer circuit may sequentially transfer the photo-charges generated by each of the plurality of photoelectric conversion elements to the first floating diffusion node in response to a successively increasing voltage.

The pixel may further include an infrared photoelectric conversion element arranged in the semiconductor substrate, the infrared photoelectric conversion element being adapted to generate photo-charges in response to wavelengths in an infrared region, and a second transfer circuit adapted to transfer the photo-charges generated by the infrared photoelectric conversion element to a second floating diffusion node.

The second transfer circuit may be a single transistor.

The plurality of photoelectric conversion elements may include a blue photoelectric conversion element, a green photoelectric conversion element formed over at least a portion of the blue photoelectric conversion element, and a red photoelectric conversion element formed over at least a portion of the green photoelectric conversion element, wherein the infrared photoelectric conversion element is formed over at least a portion of the red photoelectric conversion element.

A first photoelectric conversion element from among the plurality of photoelectric conversion elements may generate photo-charges in response to wavelengths in a red region, a second photoelectric conversion element from among the plurality of photoelectric conversion elements may generate photo-charges in response to wavelengths in a green region, a third photoelectric conversion element from among the plurality of photoelectric conversion elements may generate photo-charges in response to wavelengths in a blue region, and the second photoelectric conversion element may be arranged between the first photoelectric conversion element and the third photoelectric conversion element.

The first transfer circuit may be a transistor.

The first transfer circuit may be a MOSFET.

The first transfer circuit may be adapted to transfer photo-charges generated by each of the plurality of photoelectric conversion elements associated with the first floating diffusion node to the first floating diffusion node.

At least one of the above and other features and advantages may be separately realized by providing an image sensor, including a plurality of pixels, each of the pixels including a first transfer circuit and a second transfer circuit, wherein the first transfer circuit arranged in each of first group of pixels from among the plurality of pixels and the first transfer circuit arranged in each of second group pixels from among the plurality of pixels are connected to a first floating diffusion node, and the second transfer circuit arranged in each of the first group pixels from among the plurality of pixels and the second transfer circuit arranged in each of third group pixels from among the plurality of pixels are connected to a second floating diffusion node.

Each of the plurality of pixels may include a plurality of photoelectric conversion elements arranged in a semiconductor substrate, wherein the first transfer circuit is adapted to transfer photo-charges generated by each of the plurality of photoelectric conversion elements to the first floating diffusion node in response to respective ones of a plurality of voltages.

Each of the plurality of pixels may include a plurality of photoelectric conversion elements arranged in a semiconductor substrate, wherein the first transfer circuit is adapted to sequentially transfer the photo-charges generated by each of the plurality of photoelectric conversion elements to the first floating diffusion node in response to a successively increasing voltage.

Each of the plurality of pixels further includes an infrared photoelectric conversion element that is arranged in the semiconductor substrate and is adapted to generate photo-charges in response to wavelengths in an infrared region, wherein the second transfer circuit is adapted to transfer the photo-charges generated by the infrared photoelectric conversion element to the second floating diffusion node.

The plurality of photoelectric conversion elements may include a blue photoelectric conversion element, a green photoelectric conversion element formed over at least a portion of the blue photoelectric conversion element, and a red photoelectric conversion element formed over at least a portion of the green photoelectric conversion element, wherein the infrared photoelectric conversion element is formed over at least a portion of the red photoelectric conversion element.

At least one of the above and other features and advantages may be realized by providing an image processing device, including an image sensor, and a processor for controlling an operation of the image sensor, wherein the image sensor comprises a plurality of pixels each including a first transfer circuit and a second transfer circuit, the first transfer circuit arranged in each of first group pixels from among the plurality of pixels and the first transfer circuit arranged in each of second group pixels from among the plurality of pixels are connected to a first floating diffusion node, and the second transfer circuit arranged in each of the first group pixels from among the plurality of pixels and the second transfer circuit arranged in each of third group pixels from among the plurality of pixels are connected to a second floating diffusion node.

Each of the plurality of pixels may include a plurality of photoelectric conversion elements arranged in a semiconductor substrate, wherein the first transfer circuit is adapted to sequentially transfer photo-charges generated by each of the plurality of photoelectric conversion elements to the first floating diffusion node in response to each of a plurality of voltages.

Each of the plurality of pixels may further include an infrared photoelectric conversion element that is arranged in the semiconductor substrate and is adapted to generate photo-charges in response to wavelengths in an infrared region, wherein the second transfer circuit is adapted to transfer the photo-charges generated by the infrared photoelectric conversion element to the second floating diffusion node.

The plurality of photoelectric conversion elements may include a blue photoelectric conversion element, a green photoelectric conversion element arranged over at least a portion of the blue photoelectric conversion element, and a red photoelectric conversion element arranged over at least a portion of the green photoelectric conversion element, wherein the infrared photoelectric conversion element is arranged over at least a portion of the red photoelectric conversion element.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a plan view of a pixel array according to an exemplary embodiment;

FIG. 2 illustrates a magnified view of a portion of the plan view of the pixel array illustrated in FIG. 1;

FIG. 3 illustrates a cross-sectional view of the pixel array illustrated in FIG. 1, taken along line A-A′;

FIG. 4 illustrates a circuit diagram of an exemplary pixel of the pixel array illustrated in FIG. 1;

FIG. 5 illustrates a spectral distribution of threshold voltages of pixels included in the pixel array illustrated in FIG. 1;

FIGS. 6A, 6B, and 6C illustrate timing diagrams of exemplary control signals for controlling operation of the pixel illustrated in FIG. 4;

FIG. 7 illustrates a circuit diagram of a portion of the pixel array illustrated in FIG. 2;

FIGS. 8A, 8B, 8C, 9A, 9B, 9C, 10A, 1013, 10C, 11A, 11B, and 11C illustrate timing diagrams of control signals for controlling operations of the pixels illustrated in FIG. 7;

FIG. 12 illustrates a block diagram of an image sensor including pixels, according to an exemplary embodiment; and

FIG. 13 illustrates a block diagram of an image pickup device including the image sensor illustrated in FIG. 12.

### DETAILED DESCRIPTION

Korean Patent Application No. 10-2009-0106891, filed on Nov. 6, 2009, in the Korean Intellectual Property Office, and entitled: “Pixel and Image Processing Devices Having the Same,” is incorporated by reference herein in its entirety.

Exemplary embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when an element is referred to as being “on,” “above”, “below,” or “under” another element, it can be directly “on,” “above”, “below,” or “under” the other element, respectively, or intervening elements may also be present. In addition, it will also be understood that when an element is referred to as being “between” two elements, it can be the only layer between the two layers, or one or more intervening layers may also be present. Like reference numerals refer to like elements throughout the specification.

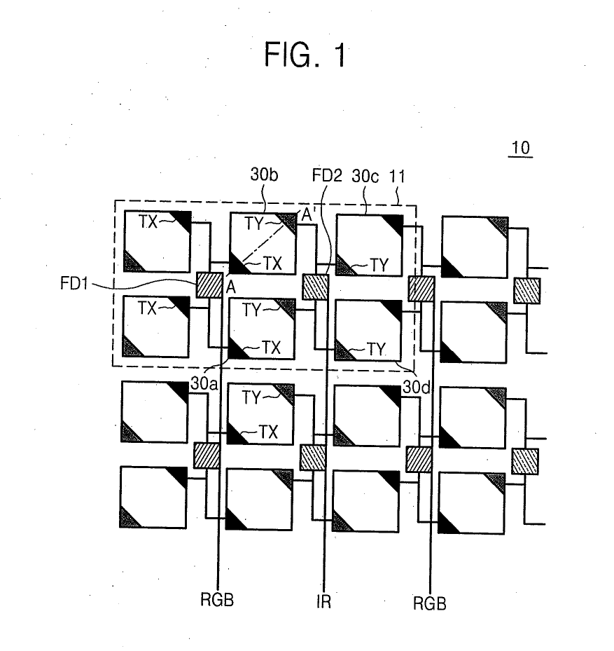

FIG. 1 illustrates a plan view of a pixel array 10 according to an exemplary embodiment. Referring to FIG. 1, the pixel array 10 includes a plurality of pixels, a first floating diffusion node FD1, which may be used as, e.g., a color floating diffusion node, and a second floating diffusion node FD2, which may be used as, e.g., an infrared diffusion node.

Each of the plurality of pixels may include a first transfer circuit TX and a second transfer circuit TY. The first transfer circuit TX included in each of the plurality of pixels may be connected to the first floating diffusion node FD1. The second transfer circuit TY included in each of the plurality of pixels may be connected to the second floating diffusion node FD2. The first floating diffusion node FD1 may be used as a node to output RGB color information RGB. The second floating diffusion node FD2 may be used as a node to output depth information IR.

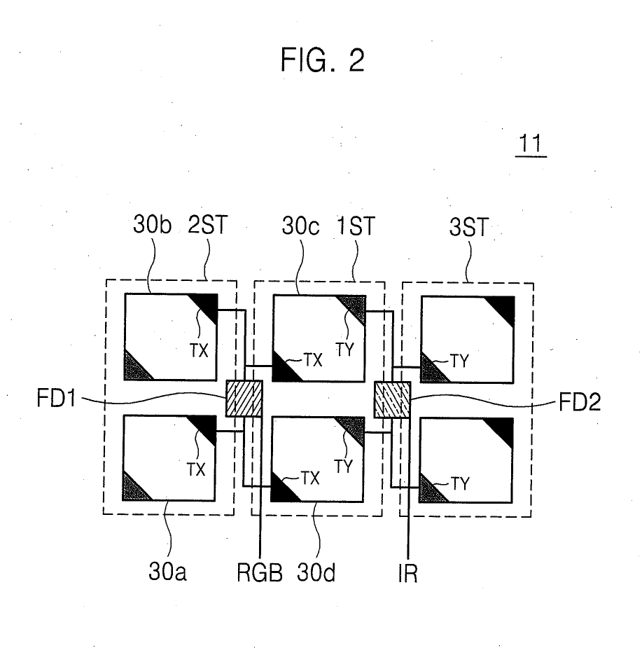

FIG. 2 illustrates a magnified view of a portion 11 of the plan view of the pixel array 10 illustrated in FIG. 1. Referring to FIGS. 1 and 2, the portion 11 of the pixel array 10 includes a plurality of pixels 30a, 30b, 30c, and 30d, the first floating diffusion node FD1, and the second floating diffusion node FD2. The portion 11 of the pixel array 10 includes a first pixel group 1ST, a second pixel group 2ST, and a third pixel group 3ST.

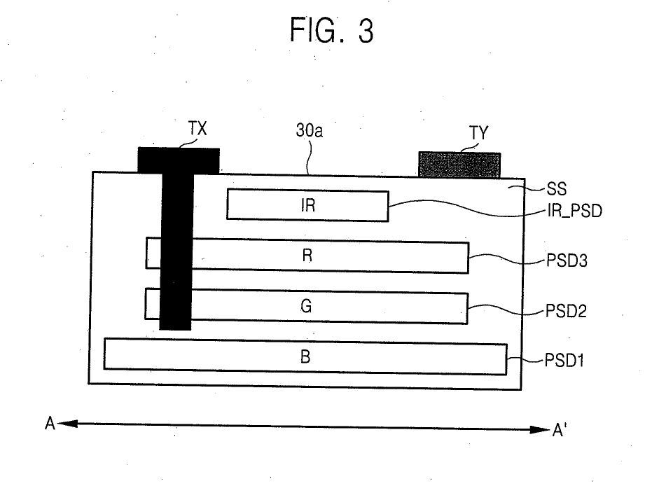

The first floating diffusion node FD1 may be arranged between the first pixel group 1ST and the second pixel group 2ST. The second floating diffusion node FD2 may be arranged between the first pixel group 1ST and the third pixel group 3ST. Each of the first, second, and third pixel groups 1ST, 2ST, and 3ST may include a plurality of pixels. A cross-section of each of the plurality of pixels is illustrated in FIG. 3.

Referring to FIG. 2, each of the plurality of pixels included in the first through third pixel groups 1ST through 3ST may include a first transfer circuit TX and a second transfer circuit TY. Each of the first transfer circuit TX and the second transfer circuit TY may function as a transfer gate and may be implemented as a MOSFET. The first transfer circuits TX associated with, e.g., arranged in each of, the first and second pixel groups 1ST and 2ST may be electrically connected to the first floating diffusion node FD1. Each of the first transfer circuits TX may sequentially transfer photo-charges generated by each of a plurality of photoelectric conversion elements associated with each of the pixels of the first and second pixel groups 1ST and 2ST to the first floating diffusion node FD1. The second transfer circuits TY associated with, e.g., arranged in each of, the first and third pixel groups 1ST and 3ST may be electrically connected to the second floating diffusion node FD2. Each of the second transfer circuits TY may sequentially transfer photo-charges generated by each of a plurality of photoelectric conversion elements associated with each of the pixels of the first and third pixel group 1ST and 3ST to the second floating diffusion node FD2.

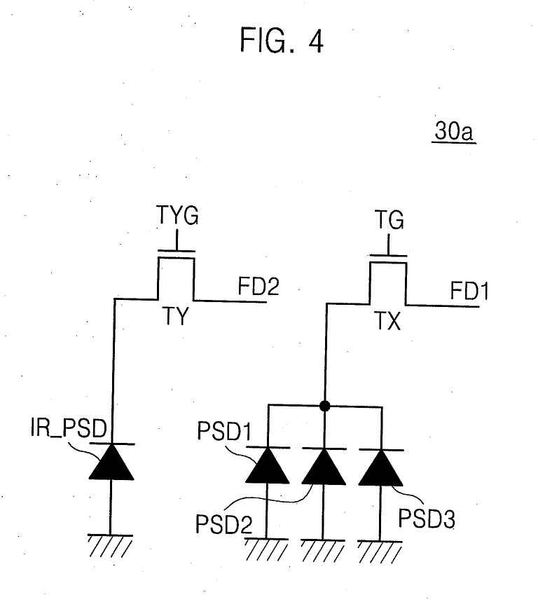

FIG. 3 illustrates a cross-sectional view of the pixel array 10 illustrated in FIG. 1, taken along line A-A′ of FIG. 1. FIG. 4 illustrates a circuit diagram of an exemplary pixel 30a of the pixel array 10 illustrated in FIG. 1. More particularly, FIGS. 3 and 4 illustrate an exemplary pixel 30a. One, some, or all of the pixels of the pixel array 10 may employ one or more of the features described below with regard to pixel 30a.

Referring to FIG. 3, the pixel 30a may include a first photoelectric conversion element PSD1, a second photoelectric conversion element PSD2, a third photoelectric conversion element PSD3, an infrared photoelectric conversion element IR_PSD, a first transfer circuit TX, and a second transfer circuit TY.

The first photoelectric conversion element PSD1 may generate photo-charges in response to wavelengths belonging to a blue region from among the wavelengths in a visible light region. The second photoelectric conversion element PSD2 may generate photo-charges in response to wavelengths belonging to a green region from among the wavelengths in the visible light region. The third photoelectric conversion element PSD3 may generate photo-charges in response to wavelengths belonging to a red region from among the wavelengths in the visible light region. The infrared photoelectric conversion element IR_PSD may generate photo-charges in response to wavelengths belonging to an infrared light region.

The second photoelectric conversion element PSD2 may be arranged over at least a portion of the first photoelectric conversion element PSD1. The third photoelectric conversion element PSD may be arranged over at least a portion of the second photoelectric conversion element PSD2. The infrared photoelectric conversion element IR_PSD may be arranged over at least a portion of the third photoelectric conversion element PSD3. In embodiments, the photoelectric conversion elements PSD1, PSD2, PSD3, and IR_PSD may be formed at different depths within a semiconductor substrate SS.

Referring to FIGS. 3 and 4, the first transfer circuit TX may be shared by the first, second, and third photoelectric conversion elements PSD1, PSD2, and PSD3. The first transfer circuit TX may be implemented as a transfer transistor. The first transfer circuit TX may transfer the photo-charges generated by the first photoelectric conversion element PSD1, the photo-charges generated by the second photoelectric conversion element PSD2, and/or the photo-charges generated by the third photoelectric conversion element PSD3 to the first floating diffusion node FD1 according to a voltage level of a control signal TG.

The second transfer circuit TY may transfer the photo-charges generated by the infrared photoelectric conversion element IR_PSD to the second floating diffusion node FD2 in response to a control signal TYG. The second transfer circuit TY may be implemented as a transfer transistor. The second transfer circuit TY may be spatially separated from the first transfer circuit TX. The second transfer circuit TY may be formed on the semiconductor substrate. Additional features of the exemplary pixel 30a will be described below.

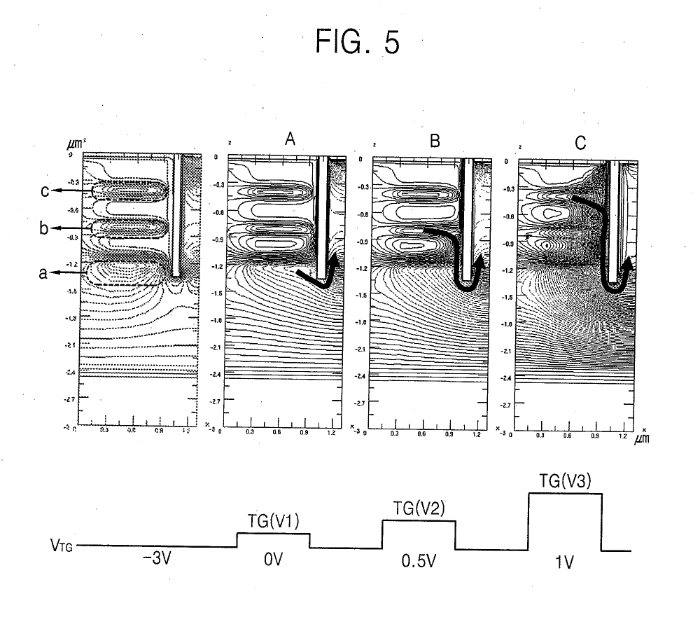

FIG. 5 illustrates an exemplary threshold voltage spectral distribution of the pixels, e.g., pixel 30a of FIGS. 3 and 4, included in the pixel array 10 illustrated in FIG. 1. Referring to FIG. 5, ‘a’ represents a spectrum of a threshold voltage of the first photoelectric conversion element PSD1 when a voltage V_{TG} having a negative level, e.g., −3V, is supplied to the first transfer circuit TX, ‘b’ represents a spectrum of a threshold voltage of the second photoelectric conversion element PSD2 when the voltage V_{TG} having a negative level, e.g., −3V, is supplied to the first transfer circuit TX, and ‘c’ represents a spectrum of a threshold voltage of the third photoelectric conversion element PSD3 when the voltage V_{TG} having a negative level, e.g., −3V, is supplied to the first transfer circuit TX.

‘A’ corresponds to a process in which the photo-charges generated by the first photoelectric conversion element PSD1 are transferred to the first floating diffusion node FD1 via the first transfer circuit TX when a voltage V_{TG} having a first level TG(V1) is supplied to the first transfer circuit TX. ‘B’ corresponds to a process in which the photo-charges generated by the second photoelectric conversion element PSD2 is transferred to the first floating diffusion node FD1 via the first transfer circuit TX when a voltage V_{TG} having a second level TG(V2) is supplied to the first transfer circuit TX. ‘C’ corresponds to a process in which the photo-charges generated by the third photoelectric conversion element PSD3 is transferred to the first floating diffusion node PD1 via the first transfer circuit TX when a voltage V_{TG} having a third level TG(V3) is supplied to the first transfer circuit TX.

Referring to FIG. 5, according to a level of the voltage V_{TG} supplied to the first transfer circuit TX, the first transfer circuit TX may selectively transfer the photo-charges generated by each of the first, second, and third photoelectric conversion elements PSD1, PSD2, and PSD3 to the first floating diffusion node FD1.

As discussed above, FIG. 4 illustrates a circuit diagram of the pixel 30a of the pixel array 10 illustrated in FIG. 1. Referring to FIG. 4, the pixel 30a may include the first photoelectric conversion element PSD1, the second photoelectric conversion element PSD2, the third photoelectric conversion element PSD3, the first transfer circuit TX, and the second transfer circuit TY.

The first transfer circuit TX may transfer the photo-charges generated by the first photoelectric conversion element PSD1, the photo-charges generated by the second photoelectric conversion element PSD2, or the photo-charges generated by the third photoelectric conversion element PSD3 to the first floating diffusion node FD1 according to the voltage level of the control signal TG. The pixel 30a may further include a circuit element capable of transferring a signal corresponding to the photo-charges transferred to the first floating diffusion node FD1 to a column line, e.g., a plurality of transistors.

According to a level of the control signal TYG supplied to the second transfer circuit TY, the second transfer circuit TY may transfer the photo-charges generated by the infrared photoelectric conversion element IR_PSD to the second floating diffusion node FD2. The pixel 30a may further include a circuit element capable of transferring a signal corresponding to the photo-charges transferred to the second floating diffusion node FD2 to a column line, e.g., a plurality of transistors.

Each of the first, second, and third photoelectric conversion elements PSD1, PSD2, and PSD3 may be a photo detection element. More particularly, each of the first, second, and third photoelectric conversion elements PSD1, PSD2, and PSD3 may be implemented as, e.g., a photodiode, a photo transistor, or a pinned photodiode. The infrared photoelectric conversion element IR_PSD may be a photo detection element. The infrared photoelectric conversion element IR_PSD may be implemented as, e.g., a photodiode, a photo transistor, a pinned photodiode, or a photo gate.

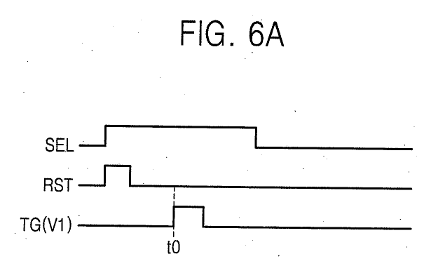

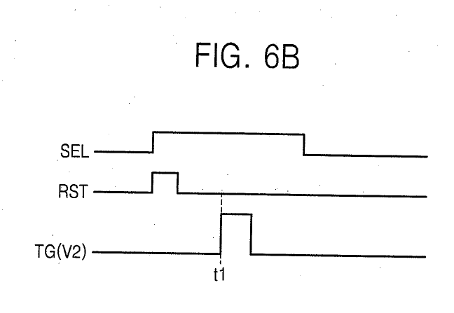

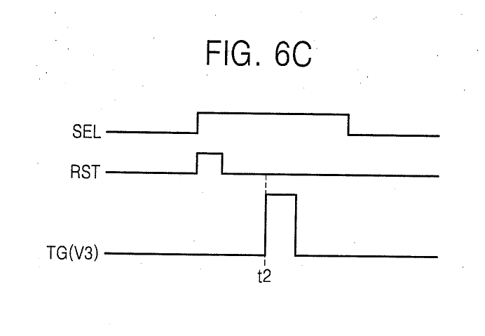

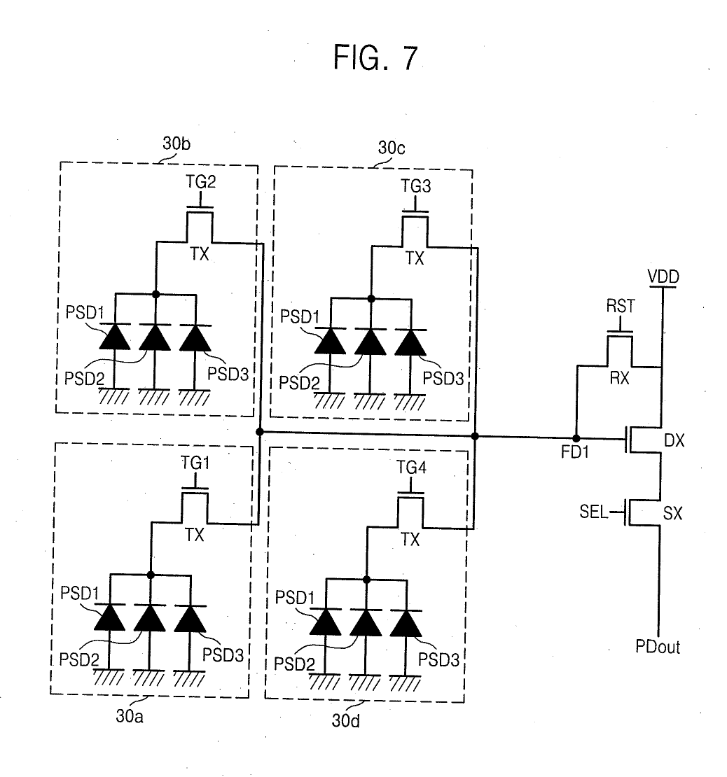

FIGS. 6A, 6B, and 6C illustrate exemplary timing diagrams of control signals SEL and RST for controlling an operation of the pixel 30a illustrated in FIG. 4. FIG. 7 illustrates a circuit diagram of the portion 11 of the pixel array 10 illustrated in FIG. 2.

Referring to FIGS. 6A, 6B, 6C, and 7, the control signals may correspond to a reset signal RST and a selection signal SEL adapted to control operations of a reset circuit RX and a selection circuit SX, respectively. More particularly, the reset signal RST and the selection signal SEL may be adapted to control operations of transistors RX and SX, respectively.

Referring to FIGS. 4 and 6A, the first transfer circuit TX of the first pixel 30a, which may be implemented as a first transfer transistor TX, may transfer the photo-charges generated by the first photoelectric conversion element PSD1 to the first floating diffusion node FD1 in response to a voltage TG(V1) having the first level input to a gate of the first transfer transistor TX at a point of time t0.

Referring to FIGS. 4 and 6B, the first transfer circuit TX of the first pixel 30a may transfer the photo-charges generated by the second photoelectric conversion element PSD2 to the first floating diffusion node FD1 in response to a voltage TG(V2) having the second level input to the gate of the first transfer transistor TX at a point of time t1.

Referring to FIGS. 4 and 6C, the first transfer circuit TX of the first pixel 30a may transfer the photo-charges generated by the third photoelectric conversion element PSD3 to the first floating diffusion node FD1 in response to a voltage TG(V3) having the third level input to the gate of the first transfer transistor TX at a point of time t2.

In embodiments, the first level may be lower than the second level, and the second level may be lower than the third level.

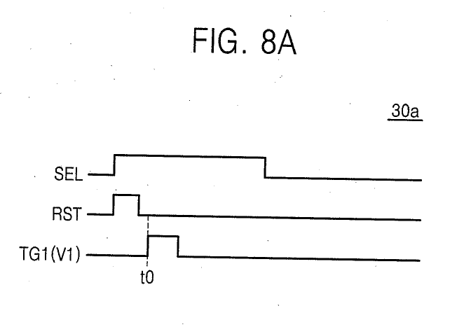

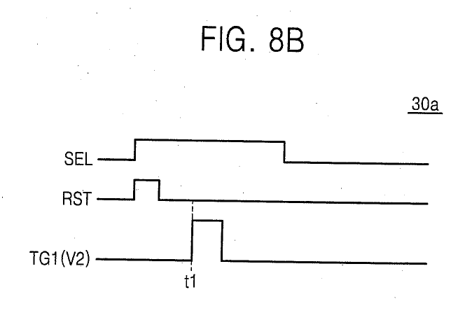

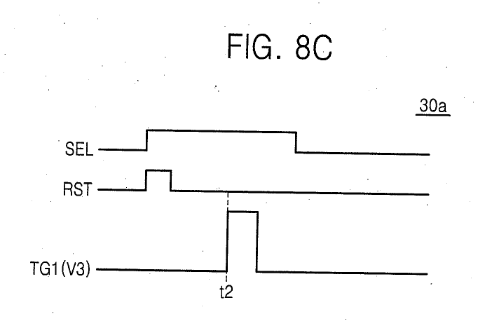

FIG. 7 illustrates a circuit diagram of the portion 11 of the pixel array illustrated in FIG. 2. FIGS. 8A, 8B, 8C, 9A, 9B, 9C, 10A, 10B, 10C, 11A, 11B, and 11C illustrate timing diagrams of control signals for controlling operations of the pixels illustrated in FIG. 7.

Referring to FIGS. 7 and 8A, the first transfer circuit TX installed in the pixel 30a may transfer the photo-charges generated by the first photoelectric conversion element PSD1 to the first floating diffusion node FD1 in response to a control signal TG1(V1) having a first level input at the point of time t0. Referring to FIGS. 7 and 8B, the first transfer circuit TX installed in the pixel 30a may transfer the photo-charges generated by the second photoelectric conversion element PSD2 to the first floating diffusion node FD1 in response to a control signal TG1(V2) having a second level input at the point of time t1. Referring to FIGS. 7 and 8C, the first transfer circuit TX installed in the pixel 30a may transfer the photo-charges generated by the second photoelectric conversion element PSD2 to the first floating diffusion node FD1 in response to a control signal TG1(V3) having a third level input at the point of time t2.

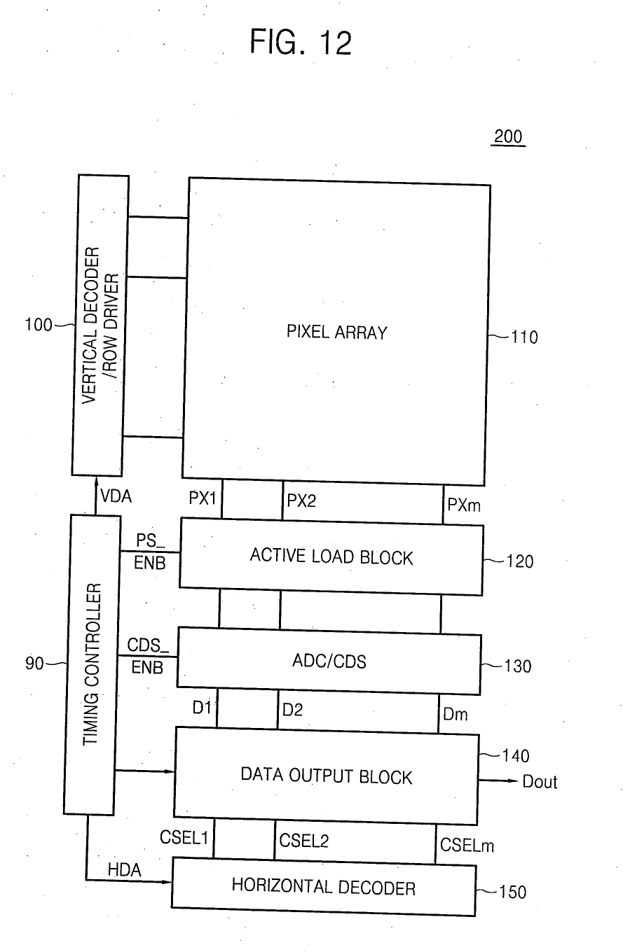

The reset circuit RX, e.g., a reset transistor, may reset the first floating diffusion node FD1 in response to the reset signal RST, which may be output, e.g., from a vertical decoder/row driver (e.g., vertical decoder/row driver 100 of FIG. 12). A drive circuit DX, e.g., a drive transistor, may play a role of a source follow buffer amplifier and may perform buffering in response to photo-charges accumulated in the first floating diffusion node FD1. The selection circuit SX, e.g., a selection transistor, may output a pixel signal PDout output from the drive circuit DX to a column line in response to the selection signal SEL, which may be output, e.g., from the vertical decoder/row driver 100 (e.g., vertical decoder/row driver 100 of FIG. 12).

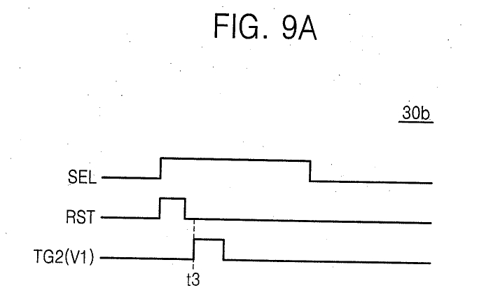

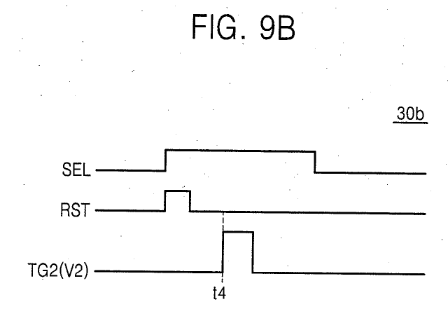

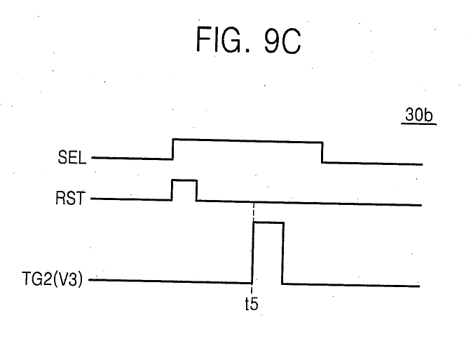

Referring to FIGS. 7 and 9A, the first transfer circuit TX installed in the pixel 30b may transfer the photo-charges generated by the first photoelectric conversion element PSD1 to the first floating diffusion node FD1 in response to a control signal TG2(V1) having a first level input at a point of time t3. Referring to FIGS. 7 and 9B, the first transfer circuit TX installed in the pixel 30b may transfer the photo-charges generated by the second photoelectric conversion element PSD2 to the first floating diffusion node FD1 in response to a control signal TG2(V2) having a second level input at a point of time t4. Referring to FIGS. 7 and 9C, the first transfer circuit TX installed in the pixel 30b may transfer the photo-charges generated by the second photoelectric conversion element PSD2 to the first floating diffusion node FD1 in response to a control signal TG2(V3) having a third level input at a point of time t5. Operations of the circuits RX, DX, and SX are the same as those described above with reference to FIGS. 8A, 8B, and 8C.

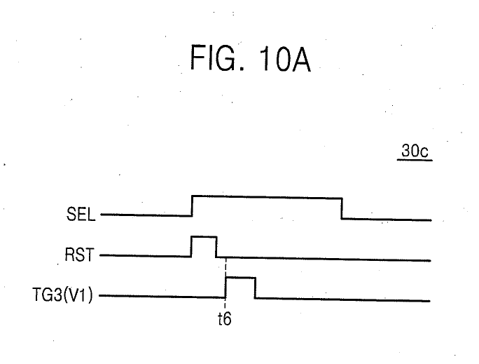

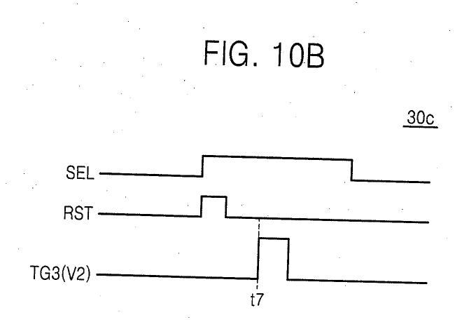

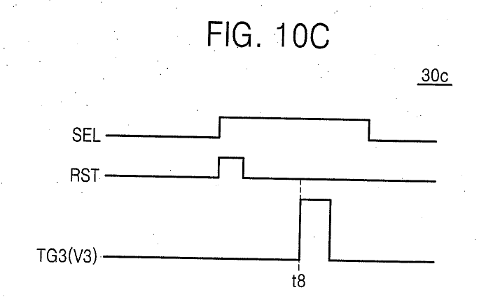

Referring to FIGS. 7 and 10A, the first transfer circuit TX installed in the pixel 30c may transfer the photo-charges generated by the first photoelectric conversion element PSD1 to the first floating diffusion node FD1 in response to a control signal TG3(V1) having a first level input at a point of time t6. Referring to FIGS. 7 and 10B, the first transfer circuit TX installed in the pixel 30c may transfer the photo-charges generated by the second photoelectric conversion element PSD2 to the first floating diffusion node FD1 in response to a control signal TG3(V2) having a second level input at a point of time t7. Referring to FIGS. 7 and 10C, the first transfer circuit TX installed in the pixel 30c may transfer the photo-charges generated by the second photoelectric conversion element PSD2 to the first floating diffusion node FD1 in response to a control signal TG3(V3) having a third level input at a point of time t8. Operations of the circuits RX, DX, and SX may be the same as those described above with reference to FIGS. 8A, 8B, and 8C.

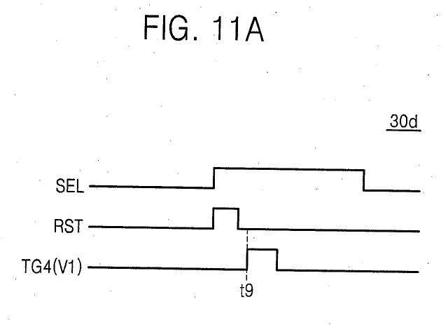

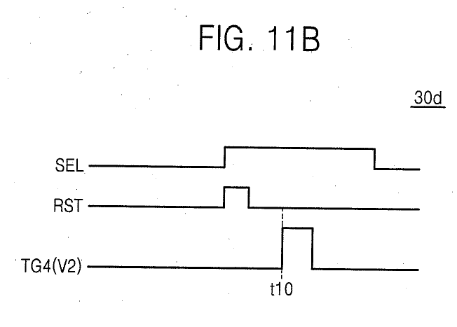

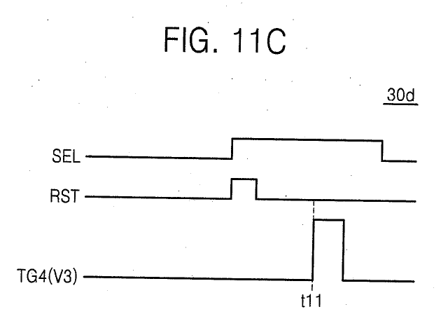

Referring to FIGS. 7 and 11A, the first transfer circuit TX installed in the pixel 30d may transfer the photo-charges generated by the first photoelectric conversion element PSD1 to the first floating diffusion node FD1 in response to a control signal TG4(V1) having a first level input at a point of time t9. Referring to FIGS. 7 and 11B, the first transfer circuit TX installed in the pixel 30d may transfer, the photo-charges generated by the second photoelectric conversion element PSD2 to the first floating diffusion node FD1 in response to a control signal TG4(V2) having a second level input at a point of time t10. Referring to FIGS. 7 and 11C, the first transfer circuit TX installed in the pixel 30d may transfer the photo-charges generated by the second photoelectric conversion element PSD2 to the first floating diffusion node FD1 in response to a control signal TG4(V3) having a third level input at a point of time t11. Operations of the circuits RX, DX, and SX are the same as those described above with reference to FIGS. 8A, 8B, and 8C.

In embodiments, points of time t0 through t11 may be different from one another. In embodiments, the first transfer circuit TX installed in each of the pixels 30a, 30b, 30c, and 30d may transfer the photo-charges generated by each of the first, second, and third photoelectric conversion elements PSD1, PSD2, and PSD3 to the first floating diffusion node FD1 in response to each of the control signals TG1(V1) through TG4(V3) input at the points of time t0 through t11, respectively.

FIG. 12 illustrates a block diagram of an image sensor 200 including pixels, according to an exemplary embodiment. Referring to FIG. 12, the image sensor 200 may include a pixel array 110, the vertical decoder/row driver 100, an active load block 120, an analog read-out circuit 130, a data output block 140, a horizontal decoder 150, and a timing controller 90.

The pixel array 110 may include a plurality of pixels, as illustrated in FIG. 1, Each of the plurality of pixels may include the plurality of photoelectric conversion elements PSD1, PSD2, PSD3, and IR_PSD, the first transfer circuit TX, and the second transfer circuit TY, as illustrated in FIG. 3. The plurality of pixels included in the pixel array 110 may be arranged, as illustrated in FIG. 2. The pixel array 110 may include a plurality of column lines PX1 through PXm.

The active load block 120 may include a plurality of active load circuits, and each of the plurality of active load circuits may be connected to a corresponding column line from among the plurality of column lines PX1 through PXm. The plurality of active load circuits may include a plurality of switches. The plurality of switches may supply bias currents to the plurality of column lines PX1 through PXm, respectively.

The analog read-out circuit 130 may be a signal processing circuit capable of processing a pixel signal output from each of the column lines PX1 through PXm. According to an embodiment, the analog read-out circuit 130 may include a plurality of correlated double sampling (CDS) circuits. Each of the CDS circuits may be connected to a corresponding column line among the plurality of column lines PX1 through PXm, and may perform CDS on the pixel signal output from the corresponding column line and output a CDSed pixel signal. According to another embodiment, the analog read-out circuit 130 may further include a plurality of analog-to-digital conversion (ADC) circuits. Each of the plurality of ADC circuits may be connected to a corresponding CDS circuit among the CDS circuits and convert the CDSed pixel signal into a digital signal.

The data output block 140 may process each output signal output from the analog read-out circuit 130 to generate an output signal Dout. The horizontal decoder 150 decodes column addresses HAD output from the timing controller 90 and outputs column selection signals CSEL1 through CSELm according to a result of the decoding. The timing controller 90 may generate a control signal VDA for controlling an operation of the vertical decoder/row driver 100, at least one control signal CDS_ENB for controlling an operation of the analog read-out circuit 130, control signals for controlling an operation of the data output block 140, and a control signal for controlling an operation of the horizontal decoder 150, in response to control signals.

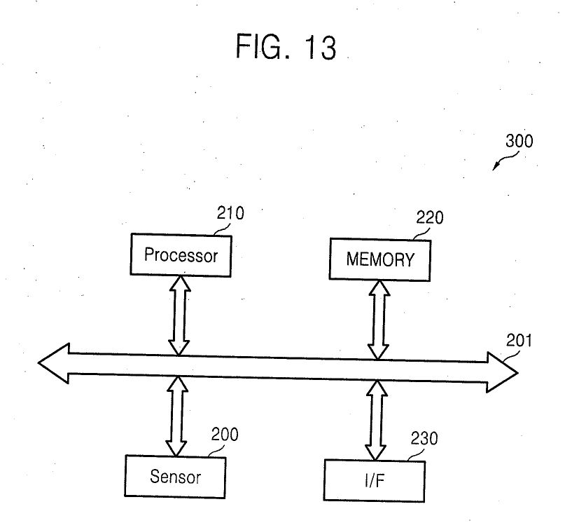

FIG. 13 illustrates a block diagram of an image pickup device 300 including the image sensor 200 illustrated in FIG. 12. Referring to FIG. 13, an image processing device, such as the image pickup device 300, may include a digital camera, a mobile phone with a built-in digital camera, or any electronic device including a digital camera.

The image pickup device 300 may process 2D image information or 3D image information. The image pickup device 300 may include the image sensor 200 and a processor 210 for controlling an operation of the image sensor 200. The image pickup device 300 may further include an interface (I/F) 230. The I/F 230 may be an image display device such as a display.

The image pickup device 300 may include a memory device 220 for storing a still image and/or a moving picture captured by the image sensor 200. The memory device 220 may be implemented as a non-volatile memory device. The non-volatile memory device may include a plurality of non-volatile memory cells.

Each of the non-volatile memory cells may be implemented as, e.g., an Electrically Erasable Programmable Read-Only Memory (EEPROM), a flash memory, a Magnetic RAM (MRAM), a Spin-Transfer Torque MRAM, a Conductive bridging RAM (CBRAM), a Ferroelectric RAM (FeRAM), a Phase change RAM (PRAM), a Resistive RAM (RRAM or ReRAM), a Nanotube RRAM, a Polymer RAM (PoRAM), a Nano Floating Gate Memory (NFGM), a holographic memory, a Molecular Electronics Memory Device, or an Insulator Resistance Change Memory.

In a pixel according to an embodiment and an image processing device including the pixel, photo-charges generated by each of a plurality of photoelectric conversion elements formed within the pixel may be transferred to a floating diffusion node by a single transfer circuit. Since the single transfer circuit is shared by the photoelectric conversion elements, integration of an image sensor may be increased.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A pixel of an image sensor, the pixel comprising:
a plurality of photoelectric conversion elements arranged in a semiconductor substrate; and
a first transfer circuit adapted to transfer photo-charges generated by at least two of the plurality of photoelectric conversion elements to a first floating diffusion node.

2. The pixel as claimed in claim 1, wherein the first transfer circuit is adapted to transfer photo-charges generated by all of the photoelectric conversion elements of the pixel to the first floating diffusion node.

3. The pixel as claimed in claim 1, wherein the first transfer circuit is adapted to transfer the photo-charges generated by each of the plurality of photoelectric conversion elements to the first floating diffusion node in response to a corresponding voltage level from among a plurality of voltage levels.

4. The pixel as claimed in claim 1, wherein the first transfer circuit is adapted to sequentially transfer the photo-charges generated by each of the plurality of photoelectric conversion elements to the first floating diffusion node in response to a successively increasing voltage.

5. The pixel as claimed in claim 1, further comprising:
an infrared photoelectric conversion element arranged in the semiconductor substrate, the infrared photoelectric conversion element being adapted to generate photo-charges in response to wavelengths in an infrared region; and
a second transfer circuit adapted to transfer the photo-charges generated by the infrared photoelectric conversion element to a second floating diffusion node.

6. The pixel as claimed in claim 5, wherein the second transfer circuit is a single transistor.

7. The pixel as claimed in claim 5, wherein the plurality of photoelectric conversion elements comprise:
a blue photoelectric conversion element;
a green photoelectric conversion element arranged over at least a portion of the blue photoelectric conversion element; and
a red photoelectric conversion element arranged over at least a portion of the green photoelectric conversion element,
wherein the infrared photoelectric conversion element is arranged over at least a portion of the red photoelectric conversion element.

8. The pixel as claimed in claim 1, wherein:
a first photoelectric conversion element from among the plurality of photoelectric conversion elements generates photo-charges in response to wavelengths in a red region;
a second photoelectric conversion element from among the plurality of photoelectric conversion elements generates photo-charges in response to wavelengths in a green region;
a third photoelectric conversion element from among the plurality of photoelectric conversion elements generates photo-charges in response to wavelengths in a blue region; and
the second photoelectric conversion element is arranged between the first photoelectric conversion element and the third photoelectric conversion element.

9. The pixel as claimed in claim 1, wherein the first transfer circuit is a transistor.

10. The pixel as claimed in claim 9, wherein the first transfer circuit is a MOSFET.

11. The pixel as claimed in claim 1, wherein the first transfer circuit is adapted to transfer photo-charges generated by each of the plurality of photoelectric conversion elements associated with the first floating diffusion node to the first floating diffusion node.

12. An image sensor, comprising a plurality of pixels, each of the pixels including a first transfer circuit and a second transfer circuit,
wherein:
the first transfer circuit arranged in each of first group of pixels from among the plurality of pixels and the first transfer circuit arranged in each of second group pixels from among the plurality of pixels are connected to a first floating diffusion node; and
the second transfer circuit arranged in each of the first group pixels from among the plurality of pixels and the second transfer circuit arranged in each of third group pixels from among the plurality of pixels are connected to a second floating diffusion node.

13. The image sensor as claimed in claim 12, wherein:
each of the plurality of pixels includes a plurality of photoelectric conversion elements arranged in a semiconductor substrate,
wherein the first transfer circuit is adapted to transfer photo-charges generated by each of the plurality of photoelectric conversion elements to the first floating diffusion node in response to respective ones of a plurality of voltages.

14. The image sensor as claimed in claim 12, wherein:
each of the plurality of pixels includes a plurality of photoelectric conversion elements arranged in a semiconductor substrate,
wherein the first transfer circuit is adapted to sequentially transfer the photo-charges generated by each of the plurality of photoelectric conversion elements to the first floating diffusion node in response to a successively increasing voltage.

15. The image sensor as claimed in claim 12, wherein:
each of the plurality of pixels further includes an infrared photoelectric conversion element that is arranged in the semiconductor substrate and is adapted to generate photo-charges in response to wavelengths in an infrared region,
wherein the second transfer circuit is adapted to transfer the photo-charges generated by the infrared photoelectric conversion element to the second floating diffusion node.

16. The image sensor as claimed in claim 15, wherein the plurality of photoelectric conversion elements comprise:
a blue photoelectric conversion element;
a green photoelectric conversion element arranged over at least a portion of the blue photoelectric conversion element; and
a red photoelectric conversion element arranged over at least a portion of the green photoelectric conversion element,
wherein the infrared photoelectric conversion element is arranged over at least a portion of the red photoelectric conversion element.

17. An image processing device, comprising:
an image sensor; and
a processor for controlling an operation of the image sensor,
wherein:
the image sensor includes a plurality of pixels each including a first transfer circuit and a second transfer circuit;
the first transfer circuit arranged in each of first group pixels from among the plurality of pixels and the first transfer circuit arranged in each of second group pixels from among the plurality of pixels are connected to a first floating diffusion node; and
the second transfer circuit arranged in each of the first group pixels from among the plurality of pixels and the second transfer circuit arranged in each of third group pixels from among the plurality of pixels are connected to a second floating diffusion node.

18. The image pickup device as claimed in claim 17, wherein each of the plurality of pixels includes a plurality of photoelectric conversion elements arranged in a semiconductor substrate,
wherein the first transfer circuit is adapted to sequentially transfer photo-charges generated by each of the plurality of photoelectric conversion elements to the first floating diffusion node in response to each of a plurality of voltages.

19. The image processing device as claimed in claim 18, wherein:
each of the plurality of pixels further includes an infrared photoelectric conversion element that is arranged in the semiconductor substrate and is adapted to generate photo-charges in response to wavelengths in an infrared region,
wherein the second transfer circuit is adapted to transfer the photo-charges generated by the infrared photoelectric conversion element to the second floating diffusion node.

20. The image pickup device as claimed in claim 19, wherein the plurality of photoelectric conversion elements comprise:
a blue photoelectric conversion element;
a green photoelectric conversion element arranged over at least a portion of the blue photoelectric conversion element; and
a red photoelectric conversion element arranged over at least a portion of the green photoelectric conversion element,
wherein the infrared photoelectric conversion element is arranged over at least a portion of the red photoelectric conversion element.
